(19) United States
(12) Patent Application Publication
(10) Pub. No.: US 2011/0308609 A1
(43) Pub. Date: Dec. 22, 2011

(54) OPTICAL FEATURES FOR SOLAR CELLS

(75) Inventor: Jeffrey B. Sampsell, Pueblo West, CO (US)

(73) Assignee: QUALCOMM MEMS Technologies, Inc., San Diego, CA (US)

(21) Appl. No.: 12/817,980

(22) Filed: Jun. 17, 2010

(51) Int. Cl. H01L 31/00; H01L 31/18

(52) U.S. Cl. 136/259; 438/72; 257/E31.127

(57) ABSTRACT

Reflectors formed in front of a solar cell reduce loss from reflections from specular conductors formed in front of the photovoltaic material in the solar cell by reflecting light otherwise incident upon the conductors onto the photovoltaic material. In one embodiment, a solar cell includes a photovoltaic material having a front surface, a conductive bus line extending along a first direction, the conductive bus line being disposed over the front surface of the photovoltaic material, a primary reflector disposed on the bus line, the primary reflector comprising a first reflective surface obtusely angled relative to the front surface of the photovoltaic material to reflect light onto the photovoltaic material, and a first secondary reflector extending along the first direction, spaced apart from the conductive bus line, the first secondary reflector comprising at least one reflective surface to reflect a portion of light reflected from the primary reflector towards the photovoltaic material.

### BACKGROUND

1. Field

The field of invention relates to photovoltaic devices.

2. Description of the Related Art

For over a century fossil fuel such as coal, oil, and natural gas has provided the main source of energy in the United States. However, fossil fuels are a non-renewable source of energy that is depleting rapidly. In addition, geopolitical issues can quickly affect the supply of such fuel. Accordingly, the need for alternative sources of energy is increasing. Solar energy is an environmentally safe renewable source of energy that can be converted into other forms of energy such as heat and electricity, and if generated efficiently may be able to reduce the World's dependency on fossil fuels.

Photovoltaic cells convert optical energy to electrical energy, and are used to convert solar energy into electrical power. Photovoltaic solar cells can be made very thin and modular. Photovoltaic cells can range in size from a few millimeters in length to tens of centimeters, and much larger. The individual electrical power output from one photovoltaic cell may range from a few milliwatts to a few watts or more. Several photovoltaic cells may be connected electrically in arrays, known as photovoltaic panels or modules, to produce electricity on a large scale for distribution by an electric grid. The photovoltaic modules, more commonly referred to as a solar panel, can be used in a wide range of devices for many applications, for example, providing power to satellites and other spacecraft, providing electricity to residential and commercial properties, charging automobile batteries, etc.

While photovoltaic modules have the potential to reduce reliance upon hydrocarbon fuels, various issues adversely affect the efficiency of photovoltaic devices. Accordingly, improvements in the efficiency of photovoltaic devices could increase usage of photovoltaic devices.

### SUMMARY

The system, method, and devices of the invention each have several aspects, no single one of which is solely responsible for its desirable attributes. Without limiting the scope of this invention, its more prominent features will now be discussed briefly. After considering this discussion, and particularly after reading the section entitled “Detailed Description of Certain Embodiments,” one will understand how the features of this invention provide advantages over other photovoltaic devices.

Certain embodiments of the invention include photovoltaic panels having reflectors to capture some light that otherwise would be reflected from conductive and/or specular electric buses that are used to carry current in the photovoltaic panels.

In one embodiment, a solar cell having a front side for receiving incident light includes a photovoltaic material having a front surface, a conductive bus line extending along a first direction, the conductive bus line being disposed over the front surface of the photovoltaic material, a primary reflector disposed on the bus line, the primary reflector comprising a first reflective surface obtusely angled relative to the front surface of the photovoltaic material to reflect a portion of light received on the reflector onto the photovoltaic material, and a first secondary reflector extending along the first direction, spaced apart from the conductive bus line, the first secondary reflector comprising at least one reflective surface to reflect a portion of light reflected from the primary reflector towards the photovoltaic material.

In another embodiment, a photovoltaic device having a front side for receiving incident light includes a photovoltaic material having a front surface, a conductive bus structure extending along a first direction, the conductive bus structure being disposed over the front surface of the photovoltaic material, wherein the bus structure comprises a cross-sectional shape with at least two reflective surfaces, each reflective surface obtusely angled relative to the front surface of the photovoltaic material to reflect light incident on the bus structure onto the photovoltaic material, and a first reflector extending along the first direction, spaced apart from the conductive bus structure, and comprising at least one reflective surface to reflect a portion of light reflected from the conductive bus structure towards the photovoltaic material.

In another embodiment, a photovoltaic device having a front side for receiving incident light and a rear side opposite the front side includes a photovoltaic material having a front surface, a conductive bus line extending along a first direction disposed over the front surface of the photovoltaic material, and a first curved secondary reflector extending along the first direction, spaced apart from the conductive bus line, and comprising two reflective surfaces.

In another embodiment, a method of manufacturing a photovoltaic device having a front side for receiving incident light and a rear side opposite the front side includes providing a conductive bus line elongated along a first direction over a front surface of a photovoltaic material, and attaching an elongated first curved reflective surface in front of the photovoltaic material along the first direction, the curved reflective surface being spaced apart from the conductive bus line.

In another embodiment, a method of manufacturing a photovoltaic device having a front side for receiving incident light and a rear side opposite the front side includes providing a conductive bus structure elongated along a first direction over a front surface of a photovoltaic material, and attaching an elongated first curved reflective surface in front of the photovoltaic material along the first direction, the curved reflective surface being spaced apart from the conductive bus structure.

In another embodiment, a photovoltaic device having a front side for receiving incident light and a rear side opposite the front side includes a photovoltaic generating means having a front surface, a conducting means for conducting electricity extending along a first direction, the conducting means being disposed over the front surface of the photovoltaic generating means, a primary reflecting means for reflecting light disposed on the conducting means, the primary reflector comprising a first reflective surface obtusely angled relative to the front surface of the photovoltaic generating means to reflect light onto the photovoltaic generating means, and a first secondary reflecting means for reflecting light extending along the first direction, spaced apart from the conducting means, the first secondary reflecting means comprising at least one reflective surface to reflect a portion of light reflected from the primary reflector towards the photovoltaic generating means.

### BRIEF DESCRIPTION OF THE DRAWINGS

Certain example embodiments disclosed herein are illustrated in the accompanying schematic drawings. However, the invention is not limited by the examples, or drawings. Certain aspects of the illustrated embodiments may be simplified or are not shown for clarity of the illustrated features. Also, features described in relation to one embodiment may be included in the other embodiments.

FIG. 1 illustrates a perspective view of an embodiment of a photovoltaic or solar cell with a primary reflector and secondary reflector according to one embodiment of the invention.

FIG. 2 further schematically illustrates a portion of a photovoltaic panel having a p-n junction.

FIG. 3 illustrates a cross-sectional view of a photovoltaic panel with bus lines.

FIG. 4 illustrates a cross-sectional view of an embodiment of a photovoltaic panel with a primary reflector.

FIG. 5 illustrates a cross-sectional view of an embodiment of a primary reflector positioned over an electrically conductive bus.

FIGS. 6A and 6B illustrate cross-sectional views of embodiments of a conductive bus structure configured as a primary reflector.

FIG. 7 illustrates a schematic of a cross-sectional view of an embodiment of a photovoltaic or solar cell with a primary reflector and secondary reflector.

FIGS. 8A-8B illustrate different embodiments of secondary reflectors.

### DETAILED DESCRIPTION OF PREFERRED EMBODIMENTS

Although certain embodiments and examples are discussed herein, it is understood that the inventive subject matter extends beyond the specifically disclosed embodiments to other alternative embodiments and/or uses of the invention and obvious modifications and equivalents thereof. Accordingly, it is intended that the scope of the inventions disclosed herein should not be limited by the particular disclosed embodiments. In any method or process disclosed herein, the acts or operations making up the method/process may be performed in any suitable sequence and are not necessarily limited to any particular disclosed sequence.

Various aspects and advantages of embodiments of the invention have been described where appropriate. However, each of the embodiments may include fewer aspects or more aspects, including aspects described in other embodiments. It should be recognized that the various embodiments may be carried out in a manner that achieves or optimizes one advantage or group of advantages as taught herein without necessarily achieving other aspects or advantages as may be taught or suggested herein. The following detailed description is directed to certain specific embodiments of the invention. However, the invention can be embodied in a multitude of different ways. The embodiments described herein may be implemented in a wide range of devices that include photovoltaic cells, modules, panels, arrays, or solar panels, all of which may be referred to herein as “photovoltaic devices.”

In this description, reference is made to the drawings wherein like parts are designated with like numerals throughout. As will be apparent from the following description, the embodiments may be implemented in a variety of devices that comprise photovoltaic material.

Photovoltaic devices are an example of a renewable source of energy that has a small carbon footprint and thus lessens impact on the environment. Photovoltaic devices can have many different sizes and shapes, e.g., from smaller than a postage stamp to several inches across, or larger. Photovoltaic devices can often be connected together to form photovoltaic cell modules that may be up to several feet long and a few feet wide. Photovoltaic modules, in turn, can be combined and connected to form large photovoltaic arrays that can be configured in different sizes for generating various power outputs. The size of an array desired for a particular application can depend on several factors, for example, the amount of sunlight available in a particular location and/or the power generation needs of the consumer. Photovoltaic devices can include electrical connections, mounting hardware, power-conditioning equipment, batteries and other equipment that is used to store and/or supply the generated power to power distribution equipment or directly to a consumer. In some embodiments, photovoltaic devices can also include other electrical components, for example, components that are powered by the photovoltaic device(s).

Photovoltaic devices often include a grid-like series of copper (or other conductive material) bus lines that carry the electricity generated by the photovoltaic device. Unfortunately, these bus lines reflect sunlight which reduces the amount of light received by the photovoltaic material of the photovoltaic device, and correspondingly reduces electricity generation. In various embodiments disclosed herein, reflectors placed on top of or around the bus lines reflect at least some of this light onto the photovoltaic material that would have otherwise been reflected away. By “recapturing” this light, these reflectors increase the efficiency of the photovoltaic device.

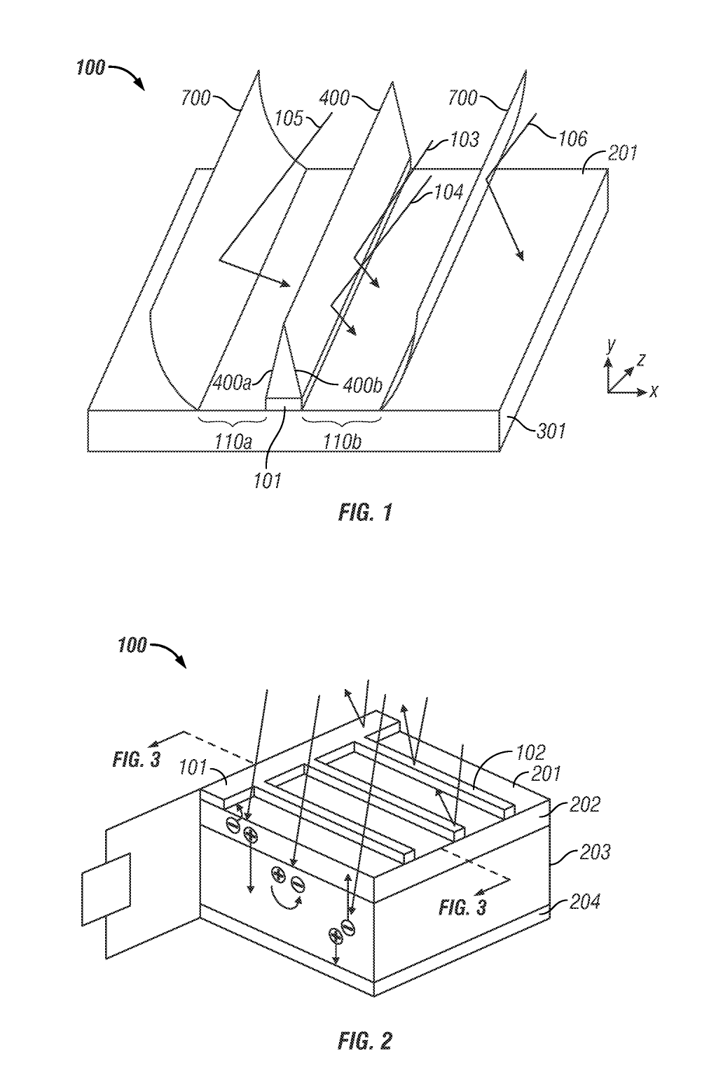

FIG. 1 illustrates a portion of one embodiment of a photovoltaic device 100 in a perspective view. The photovoltaic device 100 includes photovoltaic material 301, one or more bus lines 101, disposed on the front or light receiving surface 201 of the photovoltaic material 301, and a primary reflector 400 disposed on the bus line 101. The photovoltaic material 301 can be any material or device that is capable of using light energy to generate an electrical voltage or current. Some examples of photovoltaic materials 301 are provided herein below. The bus line 101 is representative of any bus line that is electrically connected to the photovoltaic material 301 and resides on a surface of a photovoltaic device 100 that blocks incident light from the photovoltaic material. The primary reflector 400 comprises at least one reflective surface, for example surface 400a, disposed on the bus line 101, such that light that would be incident on the top surface of bus line 101, instead is incident on the primary reflector 400.

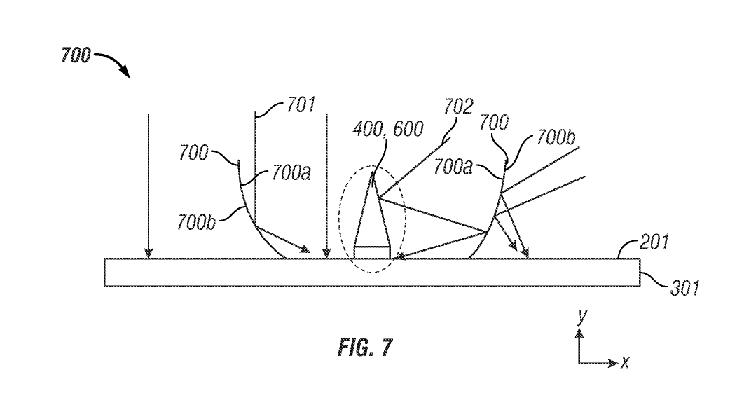

The illustrated embodiment of the photovoltaic device 100 also includes at least one secondary reflector 700 extending along at least a portion of the primary reflector 400 or the entire primary reflector, and spaced apart from the primary reflector 400. In some embodiments, the secondary reflector is connected to and/or is in contact with the light receiving surface 201. FIG. 1 illustrates an embodiment with two secondary reflectors 700, each spaced from the primary reflector 400. In some embodiments the photovoltaic device 300 only has a single secondary reflector 700 spaced from the primary reflector 400. As will be described in more detail below, the primary reflector 400 and the secondary reflector 700 are configured to reflect light that would have otherwise been reflected off the bus lines 101 back onto the photovoltaic material 301. For example, light rays 103 and 104, but for the primary reflector 400, would have been incident on the bus line 101, and reflected into the ambient environment. A cross-sectional view of the photovoltaic device embodiment illustrated in FIG. 1 is provided in FIG. 7, and certain additional aspects of this embodiment are described in the corresponding description.

Due to the bus lines being located on a portion of the collection surface of the photovoltaic device, there is an inherent trade-off between the size of the bus lines 101 and the amount of photocurrent that can be generated. As the lines become smaller, ohmic losses of the bus lines result in a decrease in the solar cell output voltage. As the lines become bigger, more solar cell 100 area is covered, the total number of generated carriers decreases, and the solar cell 100 current output drops. The final configuration may be determined through an optimization process which can consider ohmic loss and current generation surface area. However, even if bus line area and current generation are simultaneously optimized, a given percentage of current generation surface area is lost due to the presence of the overlying conductive busses. For example, the percentage of a solar cell covered by conductive bus lines 101 may be between about 5 and 15 percent.

One issue hindering widespread adoption of photovoltaic devices is their efficiency and, consequently, their cost. The seemingly small amount of light (and corresponding power generation) lost due to reflection by the conductive bus lines is very important in the solar cell context because the solar cell business model relies on amortizing solar cell cost over a long period of time. Therefore, even relatively small increases in solar cell efficiency can have a large impact on amortization time. Another important factor to consider for improved solar cell 100 designs is that solar cell production lines are very costly, and large performance improvements may require expensive upgrades. Therefore, improvements to the efficiency of a photovoltaic device that can be implemented in current factories are highly valued.

As shown in FIG. 1, non-imaging optical features, such as tapered bus ridge 400, may be placed on top of non-photon-collecting portions of solar cells 100 to recover light that would have otherwise been absorbed or reflected by the non-photon-collecting features without generating photovoltaic power. For example, one non-photon-collecting feature in a solar cell 100 is bus line 101. Typically, bus line 101 comprise a flat top surface which may reflect light incident on the bus line 101 into the ambient environment, the energy in this light thereby being lost. Bus line 101 are generally elongated in one of the two directions that are perpendicular to a line normal to the front surface of the photovoltaic device 100, i.e., elongated along the z-axis as shown in FIG. 1. The dimension of the cross-sectional shape of the bus line 101 in the x-y plane along the x-axis is greater than the dimension of the cross-sectional shape of the bus line 101 along the y-axis. As illustrated, the cross-sectional shape of the bus line 101 is rectangular, but other cross-sectional shapes are possible. As used herein and with reference to FIG. 1, the “length” of the bus line 101 refers to its dimension along the z-axis, the “width” of the bus line 101 refers to its dimension in the x-axis, and the “height” refers to its dimension along the y-axis. The length and the width of the bus line are along directions parallel to the top surface of photovoltaic device 100, while the height is perpendicular to the top surface of the photovoltaic device 100.

As shown in FIG. 1, in one embodiment, tapered bus ridges 400 are disposed on top of the photovoltaic device 100. The tapered bus ridges 400 may comprise any cross-sectional shape, such as a polygonal cross-sectional shape, that decreases the amount of light reflected into the ambient environment when compared to the amount of light reflected into the ambient environment by a flat bus line. In some embodiments, the tapered bus ridges 400 look similar to an elongated roof top. Hence, unlike a flat bus line, the cross-sectional shape of the tapered bus ridges 400 may have an appreciable height in the vertical direction, i.e., the y-axis, although it is not necessary that the vertical dimension of the tapered bus ridges 400 be greater than its width. In some embodiments, the sides 400a, 400b of the tapered bus ridge 400 are curved, non-planar, or faceted. In some embodiments, the tapered bus ridge 400 may replace the bus line 101 altogether, while in other embodiments the tapered bus ridge 400 may be placed on top of or over the bus line 101.

Further advantages can be achieved by including other structures along with the tapered bus ridge 400. For example, a hollow trough-like structure 700 may be placed in front of the photovoltaic device 100 and horizontally spaced from the tapered bus ridge 400 in the x-direction. Hollow trough-like structure 700 may, in some embodiments, be elongated in a direction parallel to the direction in which the tapered bus ridge 400 is elongated, i.e., along the z-axis. As illustrated in FIG. 1, there are two hollow trough-like structures 700, both horizontally spaced apart, along the x-axis, from the tapered bus ridge 400 by a distance, as shown by distances 110a, 110b. In some embodiments, the hollow trough-like structures 700 may be equally distant from the tapered bus ridge 400, and hence distances 110a and 110b may be equal, while in other embodiments, distances 110a and 110b may not be equal. In various embodiments, the trough-like structures 700 may come in different cross-sectional shapes, similar to a compound parabolic collector (CPC). As shown and described in FIG. 7 and the corresponding description, the hollow trough-like structures 700 may improve the efficiency over the simple tapered bus ridge 400.

The various embodiments of the primary reflector 400 and/or secondary reflector 700 of FIG. 1 may help improve the efficiency of a photovoltaic device 100. As illustrated in a representation of a portion of a solar panel FIG. 2, the photovoltaic device 100 may include a network of conductive bus lines 101, 102, including major bus lines 101 and minor bus lines 102, that are on a front surface 201 of the photovoltaic device and electrically connected to photovoltaic material 203. The major bus lines 101 may also include pads for electrically connecting tabs that allow for the electrical connection of multiple cells together. Throughout this description, statements made relative to bus line 101 may be applied to any conductor disposed on the photovoltaic device 100.

Photons entering the photovoltaic material 203 generate charge carriers throughout the solar cell 100 (except in the shadowed areas under the bus lines 101, 102. The negatively and positively charged carriers (electrons and holes respectively), once generated, can travel only a limited distance through the substrate material (e.g., the photovoltaic material) before they are trapped by imperfections in the substrates or recombine to return to a non-charged neutral state. Consequently, if current was collected only at the edge of the solar cell 100, very little current would be collected. Accordingly, photovoltaic devices can include a network of overlying conductors (e.g., bus lines 101 and 102) that collect current over the entire surface of the solar cell 100 to minimize current losses. Carriers are collected by the minor bus lines 102 and flow into the major bus lines 101. The major bus lines 101 are then connected to external circuitry to collect and further distribute the generated current.

As shown in FIG. 2, a typical photovoltaic cell 100 comprises photovoltaic materials 202, 203 disposed between multiple electrodes 101, 102 and 204. As shown, these include front electrodes (such as the major bus lines 101 and the minor bus lines 102) and rear electrodes 202. In some embodiments, the photovoltaic cell 100 comprises a substrate on which a stack of layers is formed. The photovoltaic material of a photovoltaic cell 100 may comprise a semiconductor material such as silicon. In some embodiments, the photovoltaic active region of the photovoltaic cell 100 may comprise a p-n junction formed by contacting an n-type photovoltaic semiconductor material 202 and a p-type photovoltaic semiconductor material 203 as shown in FIG. 2. Such a p-n junction may have diode-like properties and may therefore be referred to as a photodiode structure as well. In other embodiments, layers 202 and 203 may be inverted compared to the embodiment shown in FIG. 2.

When the front surface 201 of the active photovoltaic material is illuminated, photons transfer energy to electrons and holes in the active region. If the energy transferred by the photons is greater than the band-gap of the semiconducting material, the electrons may have sufficient energy to enter the conduction band. An internal electric field is created with the formation of the p-n junction. The internal electric field operates on the energized electrons to cause these electrons to move thereby producing a current flow in an external circuit 205. The resulting current flow may be used or stored. In some embodiments, the current may be used to generate power for an electric grid.

In some embodiments, the p-n junction shown in FIG. 2 can be replaced by a p-i-n junction wherein an intrinsic or un-doped semiconducting layer is sandwiched between a p-type and an n-type semiconductor. A p-i-n junction may have higher efficiency than a p-n junction. In some other embodiments, the photovoltaic cell 100 can comprise multiple junctions.

The photovoltaic active layer(s) may be formed by any of a variety of light absorbing, photovoltaic materials. Photovoltaic materials may comprise crystalline silicon (c-silicon), amorphous silicon (α-silicon), cadmium telluride (CdTe), copper indium diselenide (CIS), copper indium gallium diselenide (CIGS), light absorbing dyes and polymers, polymers dispersed with light absorbing nanoparticles, III-V semiconductors such as GaAs, etc. Other materials may also be used. The light absorbing material(s) where photons are absorbed and transfer energy to electrical carriers (holes and electrons) is referred to herein as the “photovoltaic material” of the photovoltaic cell 100, and this term is meant to encompass multiple active sub-layers. In some contexts, “photovoltaic material” may also refer to any material that is a part of the photovoltaic device 100, including the bus line 101. The material for the photovoltaic active layer can be chosen depending on the desired performance and the application of the photovoltaic cell 100.

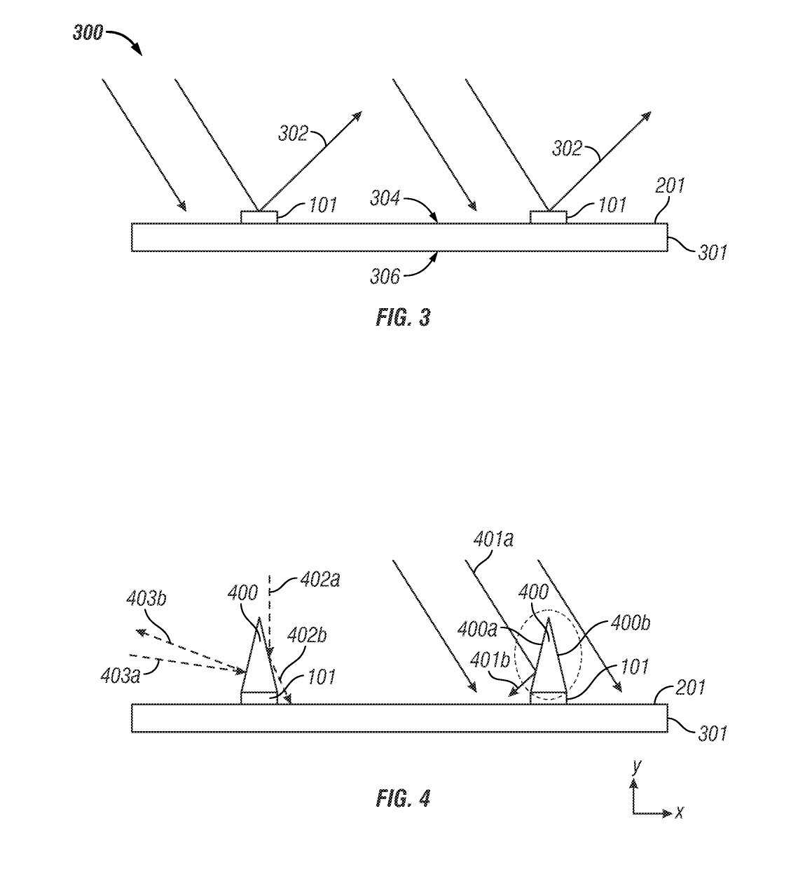

FIG. 3 shows a cross-sectional view of a portion of one embodiment of a photovoltaic device 300. As illustrated in FIG. 3, the photovoltaic device 300 includes photovoltaic material 301 which has a generally planar front surface 201. Although not shown in FIG. 3, the photovoltaic material 301 can include layers 202, 203, 204 as illustrated in FIG. 2. The photovoltaic device 300 includes conductive bus lines 101 in electrical communication with the photovoltaic material 301. The photovoltaic device 300 has a front side 304 for receiving incident light and a rear side 306 opposite the front side. The front side 304 of the photovoltaic device 300 includes conductive bus lines 101 disposed over a front surface 201 of the photovoltaic material 301. As illustrated by light rays 302, the bus lines 101 contribute to losses by reflecting light away from the photovoltaic material 301 that would otherwise be incident thereon. In addition, some light energy may be lost through absorption of incident light by the conductive bus lines 101.

To help prevent this energy loss, light turning features may be integrated with photovoltaic devices to reduce light lost due to reflection from the bus lines 101. In some embodiments, a primary reflector may be disposed on the bus line 101 to reflect at least a portion of light that would have been reflected by the bus line 101, onto the photovoltaic material 301. Additionally, in some embodiments, secondary reflectors may also be used to reflect ambient and/or incident light as well as light reflected by the primary reflector.

For example, FIG. 4 illustrates a cross section of one embodiment of a photovoltaic device where the bus line 101 is covered by a primary reflector 400. The primary reflector 400 is configured to reflect light that would have otherwise been reflected off the bus line back onto the photovoltaic material 301. As shown in FIG. 4, the bus line 101 is disposed over the front surface 201 of the photovoltaic material 301. While the embodiment shown in FIG. 4 illustrates the conductive bus line 101 physically touching the photovoltaic material 301, it is understood that there may be one or more layers between the photovoltaic material 301 and the bus line 101. In such embodiments, the bus line 101 is at least in electrical contact with the photovoltaic material 301. Furthermore, while the front surface 201 of the photovoltaic material 301 is shown as planar, in other embodiments, the front surface of the photovoltaic material 301 may not be planar but may instead include a contoured, curved or non-planar surface.

As illustrated in FIG. 4, the bus line 101 extends along a first direction perpendicular to the planar surface of the page. In other words, the bus line 101 extends in a direction parallel to the front surface 201 of the photovoltaic material 301. Primary reflectors 400 may also extend along the same direction as the bus line 101. The primary reflector 400 may extend along the entire length of the bus line 101, or may only extend along a portion thereof, depending upon the application. The primary reflector 400 may comprise one or more reflective surfaces, for example, first and second reflective surfaces 400a, 400b. In some embodiments, the first and second reflective surfaces 400a, 400b may be planar, while in others they may be curved. The first and second reflective surfaces 400a, 400b may be obtusely angled relative to the front surface 201 of the photovoltaic material 301. As illustrated by light rays 401a, 401b and 402a, 402b, depending upon the angle of the first and second reflective surfaces 400a, 400b, the reflective surfaces may facilitate the reflection or redirection of light onto the photovoltaic material 301. That is, incident light that would have otherwise been reflected away from the photovoltaic material 301 by the bus lines 101 may be reflected onto the photovoltaic material 301 by the primary reflectors 400. In this way, the primary reflectors 400 may improve the efficiency of a photovoltaic device 400. However, as illustrated by ray 403a and 403b, light arriving at very high angles of incidence (when measured from normal to the front surface 201 of the photovoltaic material 301) may be reflected away toward ambient and lost. In some cases, such light may not have been reflected by the bus line 101 had the primary reflector 400 not been present.

As shown in FIG. 5, the primary reflector includes a first reflective surface 400a that forms an angle θ₁ relative to the front surface 201 of the photovoltaic material 301. Similarly, in some embodiments, the primary reflector 400 may also include a second reflective surface 400b that forms an angle θ₂ relative to the front surface 201 of the photovoltaic material. In a preferred embodiment, both angles θ₁ and θ₂ are greater than 90° and are therefore referred to herein as “obtuse.” However, it is understood that angles θ₁ and θ₂ may be different obtuse angles, or they may be the same. In a preferred embodiment, the primary reflector 400 has a triangular-shaped cross section. However, the primary reflector 400 may have other cross-sectional shapes, such as trapezoidal, rhombic, or other polygonal and non-polygonal cross-sectional shapes. For example, at least a portion of one or both of the first and second reflective surfaces 400a, 400b may be curved and need not be straight or planar.

While FIGS. 4 and 5 show the primary reflector 400 disposed over bus line 101, the primary reflector 400 may, in some embodiments, be formed over any reflective surface on the solar cell 100. For example, the primary reflector 400 may be formed over major bus lines 101, minor bus lines 102, and/or tabs.

To make a conductive bus line 101 with a primary reflector 400 disposed over it, a primary reflector 400 comprising an elongated metal or metalized plastic body, of a triangular or other cross-sectional shape, may be pasted onto one or more bus lines 101 with an adhesive or solder. A metalized plastic body, for example, may refer to a solid or hollow plastic body which has an outer layer of metal. Methods for forming such a layer of metal to form a metalized plastic body are known in the art and include sputtering, spray coating, electrostatic painting, and other techniques. The primary reflector 400 (the metal or metalized plastic body) may be, in some embodiments, hollow. The solar cell 100 may then be heated in a reflow oven. Other methods of attaching a primary reflector 400 onto a conductive bus line 101 include using a conductive epoxy. Alternatively, non-conductive glues or epoxies may be used if electrical connection between the bus line 101 and the first and second reflective surfaces 400a, 400b is undesirable or not necessary for a given application.

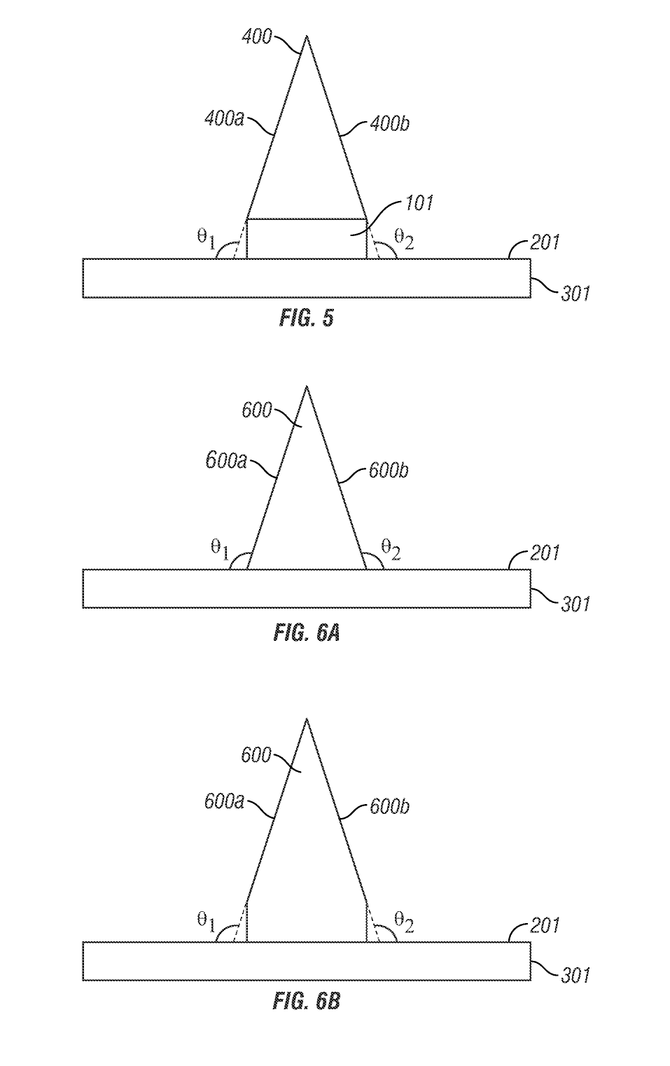

As illustrated in FIG. 5, the primary reflector 400 is shown as disposed on the bus line 101. In such embodiments, the primary reflector 400 and the bus line 101 may be referred to as a composite conductive bus structure 400. However, in some embodiments, the primary reflector may be integrated with the bus line to form a single, integrated conductive bus structure 600 as shown in FIG. 6A. Such a conductive bus structure 600 may provide both the electrical conductivity of the conductive bus line 101 of FIG. 5 as well as the optical features of the primary reflector 400. The conductive bus structure 600 is disposed over the front surface of the photovoltaic material 301, but need not be in physical contact with the photovoltaic material 301, so long as it is in electrical contact with the photovoltaic material 301. While shown in FIG. 6A as having a triangular-shaped cross section, the conductive bus structure 600 may have other polygonal or non-polygonal cross-sectional shapes. For example, the conductive bus structure 600 may have a cross-sectional shape resembling a rectangle on the bottom, with a triangular shape on the top, such as is illustrated in the embodiment of FIG. 6B. The conductive bus structure 600 may include one or more reflective surfaces, here shown as having two reflective surfaces 600a, 600b. In some embodiments, the reflective surfaces 600a, 600b can be obtusely angled relative to the front surface 201 of the photovoltaic material 301, however, angles θ₁ and θ₂ need not be equal. Like the primary reflector of FIGS. 4 and 5, the conductive bus structure 600 may increase the amount of light incident onto the photovoltaic material when compared to a simple rectangular cross-sectioned bus line 101 (as shown in FIG. 3).

In some embodiments, the conductive bus structure 600 may comprise a single piece of metal or conductive material. In other embodiments, the conductive bus structure 600 may be made of a non-metallic material, such as a plastic, that also contains metal on at least one of its outer surfaces. In some embodiments the conductive bus structure 600, whether metallic or metalized plastic, may be hollow. The metal on the outer surface of a conductive bus structure 600 need not be uniform. For example, portions of a conductive bus structure 600 that touch or are most directly in electrical contact with the photovoltaic material 301 may have a thicker outer metal layer than the reflective surfaces 600a, 600b. Conductive bus structure 600 may advantageously increase the efficiency of the solar cell 100 by increasing the light incident on the photovoltaic material 301 while also increasing the amount of conductor available for conducting the photo-generated current, thereby reducing ohmic and other electric losses.

The size and shape of the primary reflector 400 of FIGS. 4 and 5 and the conductive bus structure 600 of FIG. 6 can be optimized so as to increase the efficiency of a solar cell 100, especially when compared to a solar cell 100 having a bus with a rectangular cross-section of an equal footprint on the surface of the solar cell 100. In some embodiments, where the primary reflector 400 and/or the conductive bus structure 600 has a triangular cross section, the height of the triangle can be increased so as to reflect more light onto the photovoltaic material 301. However, increasing the height of the triangle can also reduce the amount of light reflected onto the photovoltaic material 301 for high angles of incidence (when measured from normal to the front surface 201 of the photovoltaic material 301). In some embodiments of the triangular-shaped cross section bus structures, one or more of surfaces 400a, 400b and/or 600a, 600b may be curved. In some embodiments, the ratio of the width to the height of the triangle (w/h) ranges from 1.0 to about 0.25.

While composite conductive bus structures 600 may be formed as described above, an integrated conductive bus structure 600 may consist of a solid or hollow metal or metalized plastic body. The body, or plurality of bodies, may then be placed in the desired pattern onto the solar cell (e.g., a grid-like pattern as in FIG. 2) and an electrical connection between the body (or bodies) and the photovoltaic material 301 may be made. The electrical connection may comprise placing the body (or bodies) in direct physical contact with the photovoltaic material 301, or through some conductive intermediary. The integrated conductive bus structure 600 may also be electrically connected to other buses in the solar cell 100, such as to minor bus structures, if any.

Now referring to FIG. 7, in addition to the primary reflector 400 and/or the conductive bus structure 600, photovoltaic devices may include secondary reflectors 700. Although the terms “primary” and “secondary” are used, this is done for the purposes of clarity, and these labels are not intended to suggest that one kind of optical feature is more or less important than the other. Indeed, in some embodiments, there may only be a “secondary” reflector, without a “primary” reflector.

FIG. 7 illustrates a schematic of a primary reflector 400 with secondary reflectors 700 disposed on opposite sides of the bus line 101, where the secondary reflectors 700 are spaced apart from the primary reflector 400 along the x-axis. Although illustrated as a primary reflector 400 formed over a bus line 101, it is understood that in other embodiments, the primary reflector 400 and bus line 101 may be replaced by an integrated conductive bus structure 600. The secondary reflectors 700, in some embodiments, may be integrated with a solar cell 100 that only has a bus line 101, without a primary reflector 400 or conductive bus structure 600.

As illustrated in FIG. 7, in some embodiments, the secondary reflectors 700 may have a relatively thin cross-sectional profile, for example, secondary reflectors 700a, 700b are illustrated having a cross-sectional shape of a thin curved line. For example, in some embodiments, the secondary reflectors may have a thickness of less than about 0.25 mm thick. In other embodiments, the secondary reflectors have a thickness between about 0.30 and 0.50 mm. In some embodiments, the secondary reflectors 700 are curved and extend along the same direction as the bus line 101 or conductive bus structure 600. The secondary reflectors 700 can be spaced apart from the conductive bus line 101 or conductive bus structure 600 and can be aligned in parallel with the primary reflectors 400 and the bus lines 101. For example, in some embodiments, the secondary reflectors may be spaced apart from the conductive bus line 101 or conductive bus structure 600 by between about 2 and 5 mm. The secondary reflectors 700 may include at least one reflective surface (shown here as having two reflective surfaces 700a, 700b) to reflect at least a portion of light reflected from the conductive bus structure 600 towards the surface of the solar cell (e.g., photovoltaic material 301). As shown by rays 701 and 702, the secondary reflectors may reflect both ambient light (ray 701) and light reflected by the primary reflector 400 or conductive bus structure 600 (ray 702). While FIG. 7 illustrates two secondary reflectors 700, it is understood that in some embodiments, only one secondary reflector 700 positioned on either side of the primary reflector 400 or conductive bus structure 600 may be used.

In some embodiments, the secondary reflectors 700 can be configured to have different shapes. As illustrated in FIG. 7, in some embodiments, the secondary reflectors 700 each includes a lower portion connected to the front surface 201 of the photovoltaic material 301. However, in some embodiments, it may be advantageous for the secondary reflector 700 not to extend all the way down to the front surface 201 of the photovoltaic material 301. For example, the secondary reflector 700 may not contact the front surface 201 of the photovoltaic material 301, but rather contacts a glass or other transparent layer formed over the photovoltaic material 301.

In embodiments with two (first and second) secondary reflectors 700 on opposing sides of the primary reflector 400 and/or conductive bus structure 600, the first and second secondary reflector 700 may comprise an upper portion that is spaced further apart than the lower portions of the first and second secondary reflectors 700.

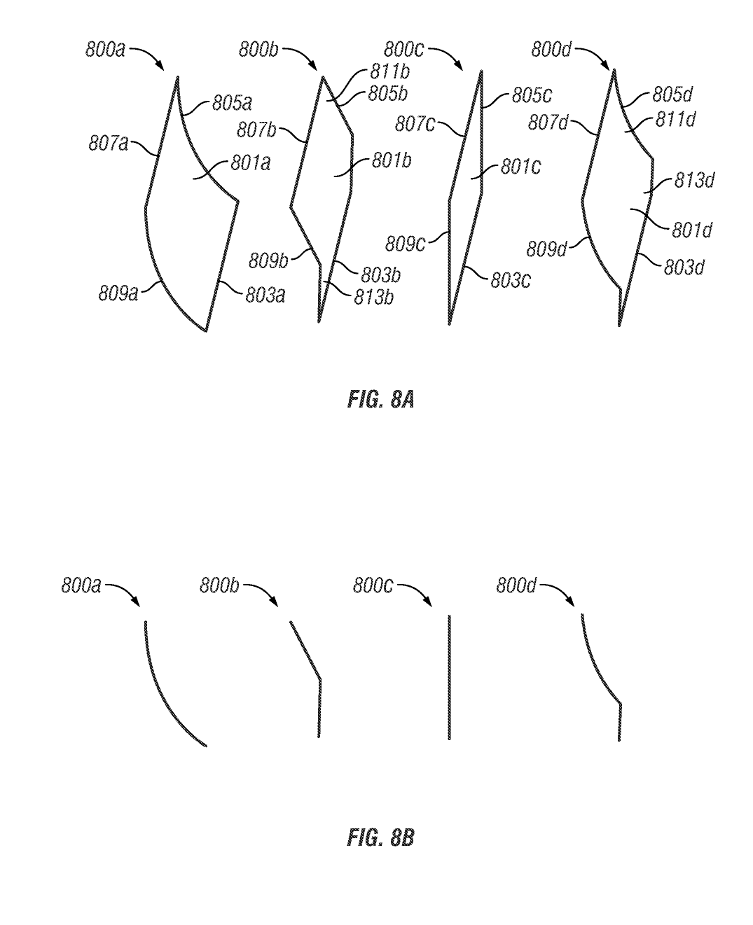

As shown in FIGS. 8A-8B, secondary reflector 800a-b may have a variety of comprise different shapes. The secondary reflectors 800a-b may include a reflective surface 801a-d bounded by a lower edge 803a-d, an upper edge 807a-d, and lateral edges 805a-d, 809a-d. The secondary reflectors 800a-d can comprise various highly reflective materials. In some embodiments, the material(s) for the secondary reflectors 800a-d can be chosen based on their coefficients of thermal expansion such that the coefficients of thermal expansion of the secondary reflectors 800a-b are close to the coefficient of thermal expansion of the photovoltaic material 301. In one embodiment the coefficient of thermal expansion of a secondary reflector 800a-d substantially matches the coefficient of thermal expansion of the photovoltaic material 301 such that the secondary reflector 800a-d does not wrinkle when the photovoltaic material expands and/or contracts. In some embodiments, the secondary reflectors 800a-d can be ray traced and/or numerically optimized in shape. In some embodiments, the material(s) for the secondary reflectors 800a-d can be chosen by the ability to bond, adhere, or otherwise couple the secondary reflectors to the photovoltaic material 301. In some embodiment, the material(s) for the secondary reflectors 800a-d can be chosen by thermal conductivity characteristics. In one embodiment, the secondary reflectors 800a-d can have relatively high thermal conductivity characteristics.

In one embodiment, a secondary reflector 800a is a compound parabolic collector. The reflective surface 801a of secondary reflector 8001 can be concave relative to the surface of a photovoltaic material and in other embodiments, parabolic collector 800a can be convex relative to the surface of a photovoltaic material. However, other shapes of secondary reflectors are possible. For example, the secondary reflector may have several discrete portions forming different contours. For example, the reflective surface 801b of secondary reflector 800b includes two planar portions 811b, 813b that form an angle therebetween. In some embodiments, the angle formed between the two distinct planar portions 811b, 813b of secondary reflector 800b is less than 180° such that light reflected from a primary reflector can be reflected toward a photovoltaic material by the upper planar portion 811b. Hence, in some embodiments, the secondary reflector may include multiple straight or planar portions. In another embodiment, the reflective surface 801d of secondary reflector 800d includes an upper curved portion 811d and a lower planar portion 813d. Alternatively, secondary reflector 800c may have a single planar reflective surface 801c that extends generally perpendicular to the front surface 201 of the photovoltaic material 301.

Secondary reflectors 700 may be integrated with solar cells 100 in many ways. For example, a secondary reflector 700 may be attached on the front surface of the photovoltaic material 301 to extend along the same direction as bus lines 101. In such an embodiment, the secondary reflector 700 may be spaced apart from the bus line 101. The secondary reflector 700 may be pasted onto minor bus lines 102 (see FIG. 2) using a solder paste and heated in a reflow oven. Until the position of the secondary reflector 700 is set in the reflow oven, the secondary reflector 700 may be temporarily held in place using a tape or other temporary structure holding it from above.

It is understood that in the various embodiments shown in FIGS. 4-8, the solar cell 100, including primary reflectors 400, conductive bus structures 600, and/or secondary reflectors 700, may be further encapsulated in a material such as ethylene vinyl acetate (EVA) or other encapsulating material. Further, in some embodiments, a cover glass may be placed in front of the encapsulated solar cell 100. Advantageously, in embodiments with secondary reflectors 700, the encapsulation may protect the thin elongated secondary reflectors 700 from damage.

While the foregoing detailed description discloses several embodiments of the invention, it should be understood that this disclosure is illustrative only and is not limiting of the invention. It should be appreciated that the specific configurations and operations disclosed can differ from those described above, and that the methods described herein can be used in contexts other than solar cells. The skilled artisan will appreciate that certain features described with respect to one embodiment may also be applicable to other embodiments. For example, various features of the primary reflector have been discussed, and such features may be readily applicable to the secondary reflector, and vice versa.

1. A solar cell having a front side for receiving incident light, the solar cell comprising:
a photovoltaic material having a front surface;
a conductive bus line extending along a first direction, the conductive bus line being disposed over the front surface of the photovoltaic material;
a primary reflector disposed on the bus line, the primary reflector comprising a first reflective surface obtusely angled relative to the front surface of the photovoltaic material to reflect light onto the photovoltaic material; and
a first secondary reflector extending along the first direction, spaced apart from the conductive bus line, the first secondary reflector comprising at least one reflective surface to reflect a portion of light reflected from the primary reflector towards the photovoltaic material.

2. The solar cell of claim 1, wherein the at least one reflective surface is configured to also reflect a portion of ambient light towards the photovoltaic material.

3. The solar cell of claim 1, wherein the first secondary reflector comprises two reflective surfaces.

4. The solar cell of claim 1, wherein the first secondary reflector is curved.

5. The solar cell of claim 1, wherein the primary reflector comprises a planar reflective surface, and wherein the front surface of the photovoltaic material comprises a planar surface.

6. The solar cell of claim 1, wherein the primary reflector comprises a second reflective surface obtusely angled relative to the front surface of the photovoltaic material.

7. The solar cell of claim 6, further comprising a second secondary reflector extending along the first direction, the first and the second secondary reflectors disposed on opposite sides of the bus line.

8. The solar cell of claim 7, wherein the second secondary reflector is curved.

9. The solar cell of claim 7, wherein the first and second secondary reflectors each comprise a lower portion connected to the front planar surface and an upper portion, wherein the upper portions of the first and second secondary reflectors are spaced further apart than the lower portions of the first and second secondary reflectors.

10. The solar cell of claim 4, wherein the first and second secondary reflectors are configured as compound parabolic-shaped collectors

11. The solar cell of claim 4, wherein the first and second secondary reflectors each comprise two generally planar portions disposed at an angle relative to one another.

12. The solar cell of claim 4, wherein the first and second secondary reflectors each comprise a generally planar portion and a generally curvilinear portion.

13. The solar cell of claim 4, wherein the first and second secondary reflectors are generally planar.

14. A photovoltaic device having a front side for receiving incident light, the photovoltaic device comprising:
a photovoltaic material having a front surface;
a conductive bus structure extending along a first direction, the conductive bus structure being disposed over the front surface of the photovoltaic material, wherein the bus structure comprises a cross-sectional shape with at least two reflective surfaces, each reflective surface obtusely angled relative to the front surface of the photovoltaic material to reflect light incident on the bus structure onto the photovoltaic material; and
a first reflector extending along the first direction, spaced apart from the conductive bus structure, and comprising at least one reflective surface to reflect a portion of light reflected from the conductive bus structure towards the photovoltaic material.

15. The device of claim 14, wherein the first reflector comprises two reflective surfaces.

16. The device of claim 14, wherein the first reflector is curved.

17. The device of claim 14, wherein the reflective surfaces of the conductive bus structure are planar.

18. The device of claim 14, wherein the photovoltaic material comprises a planar surface.

19. The device of claim 14, wherein the cross-sectional shape of the bus structure is polygonal.

20. The device of claim 19, wherein the cross-sectional shape of the bus structure is triangular.

21. The device of claim 20, wherein the triangular cross-sectional shape of the bus structure comprises a width and a height, and wherein a ratio of the width to the height is from 1 to 0.25.

22. The device of claim 14, further comprising a second reflector extending along the first direction, the first and the second curved reflectors disposed on opposite sides of the bus structure.

23. The device of claim 22, wherein the second reflector is curved.

24. The device of claim 22, wherein the first and second curved reflectors each comprise a lower portion connected to the front planar surface and an upper portion, wherein the upper portions of the first and second curved reflectors are spaced further apart than the lower portions of the first and second curved reflectors surfaces.

25. The device of claim 22, wherein the second reflectors are configured as compound parabolic collectors.

26. A photovoltaic device having a front side for receiving incident light and a rear side opposite the front side, the photovoltaic device comprising:
a photovoltaic material having a front surface;
a conductive bus line extending along a first direction disposed over the front surface of the photovoltaic material; and
a first curved secondary reflector extending along the first direction, spaced apart from the conductive bus line, and comprising two reflective surfaces.

27. A method of manufacturing a photovoltaic device having a front side for receiving incident light and a rear side opposite the front side, the method comprising:
providing a conductive bus line elongated along a first direction over a front surface of a photovoltaic material; and
attaching an elongated first curved reflective surface in front of the photovoltaic material along the first direction, the curved reflective surface being spaced apart from the conductive bus line.

28. The method of claim 27, further comprising forming a conductive bus structure by attaching to the conductive bus line a body having a cross-sectional shape with at least two reflective surfaces, each reflective surface obtusely angled relative to the front surface of the photovoltaic material.

29. The method of claim 28, wherein the body is hollow.

30. The method of claim 27, further comprising attaching a second curved reflective surface in front of the photovoltaic material along the first direction, the first and second reflective surfaces disposed on opposite sides of the bus line.

31. A method of manufacturing a photovoltaic device having a front side for receiving incident light and a rear side opposite the front side, the method comprising:
providing a conductive bus structure elongated along a first direction over a front surface of a photovoltaic material; and
attaching an elongated first curved reflective surface in front of the photovoltaic material along the first direction, the curved reflective surface being spaced apart from the conductive bus structure.

32. A photovoltaic device having a front side for receiving incident light and a rear side opposite the front side, the photovoltaic device comprising:
a photovoltaic generating means having a front surface;
a conducting means for conducting electricity extending along a first direction, the conducting means being disposed over the front surface of the photovoltaic generating means;
a primary reflecting means for reflecting light disposed on the conducting means, the primary reflector comprising a first reflective surface obtusely angled relative to the front surface of the photovoltaic generating means to reflect light onto the photovoltaic generating means; and
a first secondary reflecting means for reflecting light extending along the first direction, spaced apart from the conducting means, the first secondary reflecting means comprising at least one reflective surface to reflect a portion of light reflected from the primary reflector towards the photovoltaic generating means.
